(19) United States
(12) Patent Application Publication
(10) Pub. No.: US 2009/0146234 A1
(43) Pub. Date: Jun. 11, 2009

(54) MICROELECTRONIC IMAGING UNITS HAVING AN INFRARED-ABSORBING LAYER AND ASSOCIATED SYSTEMS AND METHODS

(75) Inventors: Shijian Luo, Boise, ID (US); Tongbi Jiang, Boise, ID (US); J. Michael Brooks, Caldwell, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/951,528

(22) Filed: Dec. 6, 2007

(51) Int. Cl. H01L 31/0232; H01L 31/18

(52) U.S. Cl. 257/432; 438/65; 257/E31.127

(57) ABSTRACT

Infrared (IR) absorbing layers and microelectronic imaging units that employ such layers are disclosed herein. In one embodiment, a method of manufacturing a microelectronic imaging unit includes attaching an IR-absorbing lamina having a filler material to a backside die surface of an imager workpiece. An individual imaging die is singulated from the workpiece such that a section of the infrared-absorbing lamina remains attached to the individual imaging die. The individual imaging die is coupled to an interposer substrate with a portion of the IR-absorbing lamina positioned therebetween. In another embodiment, the IR-absorbing lamina is a die attach film and the filler material is carbon black.

### TECHNICAL FIELD

The present disclosure is related to microelectronic imaging units having an image sensor and methods of manufacturing such imaging units.

### BACKGROUND

Microelectronic imagers are used in digital cameras, wireless devices with picture capabilities, and many other applications. Cell phones and Personal Digital Assistants (PDAs), for example, are incorporating microelectronic imagers for capturing and sending pictures. The growth rate of microelectronic imagers has been steadily increasing as they become smaller and produce better images with higher pixel counts.

Microelectronic imagers include image sensors that use Charged Coupled Device (CCD) systems, Complementary Metal-Oxide Semiconductor (CMOS) systems, or other solid-state systems. CCD image sensors have been widely used in digital cameras and other applications. CMOS image sensors are also quickly becoming very popular because they are expected to have low production costs, high yields, and small sizes. CMOS image sensors can provide these advantages because they are manufactured using technology and equipment developed for fabricating semiconductor devices. CMOS image sensors, as well as CCD image sensors, generally include an array of pixels arranged in a focal plane. Each pixel is a light-sensitive element that includes a photogate, a photoconductor, or a photodiode with a doped region for accumulating a photo-generated charge.

One problem with current microelectronic imagers is that they are sensitive to background electromagnetic radiation. Background radiation can indirectly influence the amount of charge stored at individual pixels by altering the amount of thermally emitted charges or “dark current” within the substrate material carrying the image sensor. This altered charge can ultimately affect image sensor readout, causing image distortion or a black-out of individual pixels.

### BRIEF DESCRIPTION OF THE DRAWINGS

FIG. 1 is a cross-sectional side view of a microelectronic imaging unit including an infrared-absorbing lamina configured in accordance with an embodiment of the disclosure.

FIGS. 2A and 2B are cross-sectional side views of the imaging unit of FIG. 1 showing the infrared-absorbing lamina inhibiting the transmission and reflection of infrared light.

FIGS. 3-5 illustrate isometric and cross-sectional side views of an infrared-absorbing lamina during stages of imaging unit fabrication in accordance with an embodiment of the disclosure.

FIGS. 6 and 7 illustrate isometric and cross-sectional side views of an infrared-absorbing lamina during stages of imaging unit fabrication in accordance with another embodiment of the disclosure.

FIG. 8 is a cross-sectional side view of an infrared-absorbing lamina configured in accordance with another embodiment of the disclosure.

FIG. 9 is a top plan view of an embodiment of an infrared imaging system that includes the imaging unit of FIG. 1.

### DETAILED DESCRIPTION

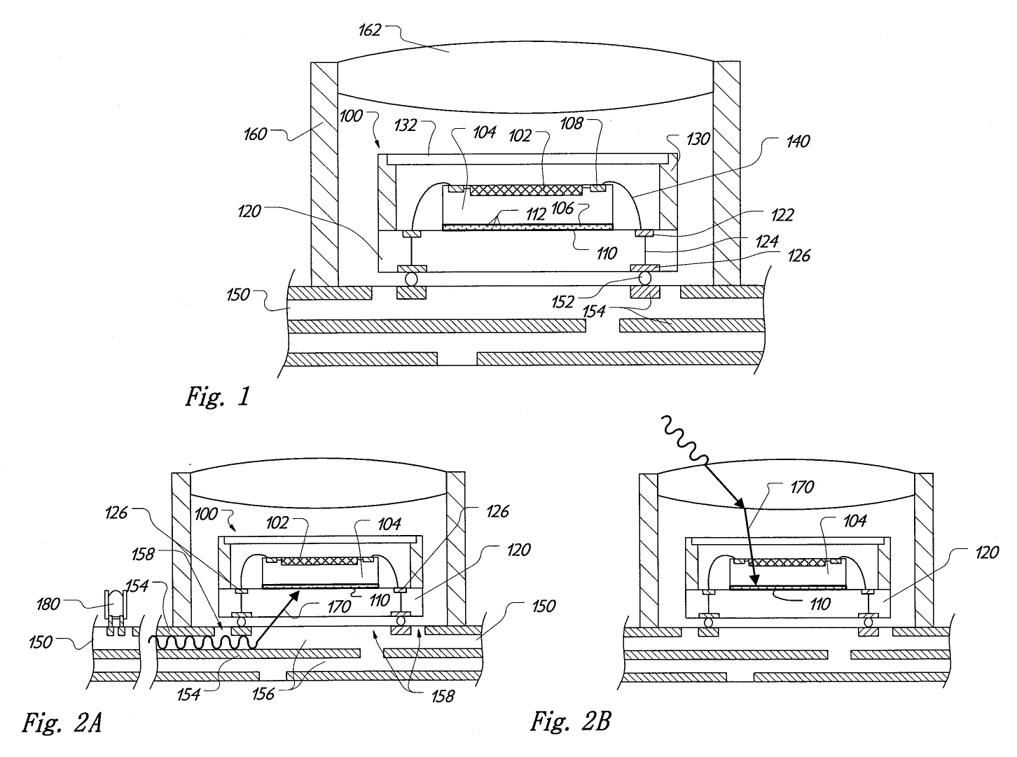

Various embodiments of imaging dies and microelectronic imaging units that include such imaging dies are described below. Imaging dies may encompass CMOS image sensors as well as various other types of CCD image sensors or solid-state imaging devices. Several details describing structures or processes associated with imaging dies, imaging units, and their corresponding methods of fabrication have not been shown or described in detail to avoid unnecessarily obscuring the description of the various embodiments. Other embodiments of imaging dies and imaging units in addition to or in lieu of the embodiments described in this section may have several additional features or may not include many of the features shown and described below with reference to FIGS. 1-9.

FIG. 1 is a cross-sectional side view of an embodiment of a microelectronic imaging unit 100. The imaging unit 100 can include an image sensor 102, an imaging die 104 carrying the image sensor 102, and an infrared (IR)-absorbing lamina or element 110 attached to a backside die surface 106 of the imaging die 104. The imaging unit 100 can also include an interposer substrate 120 (e.g., a printed circuit board or other type of substrate) coupled to the imaging die 104. The IR-absorbing lamina 110 can be a separate, discrete film, sheet, and/or adhesive between the imaging die 104 and the interposer substrate 120. For example, the IR absorbing lamina 110 can include an IR-absorbing die attach film having a polymeric backing and an at least one adhesive layer in which one or both of the backing and adhesive layer is opaque or at least partially non-transmissive to IR radiation. Such an IR absorbing die attach film can attach the interposer substrate 120 to the backside die surface 106. In a different embodiment, the IR-absorbing lamina can be a separate sheet, such as a polymeric sheet, that blocks or at least filters IR radiation. Such a sheet can be attached to the imaging die 104 and the interposer substrate 120 by a separate die attach paste. In any of the foregoing embodiments, the sheets, films, and/or adhesives can include an IR-absorbing material that blocks or otherwise limits the transmission of IR radiation to the imaging die 104. In many embodiments, the IR-absorbing lamina 110 includes a filler material 112 that is in particle or particulate form. The filler material 112 can include an organic material, such as carbon black, or an inorganic material, such as aluminum trihydroxide, aluminum borate, calcium borate, calcium carbonate, lanthanum borite (LaB₆), and/or indium tin oxide. In general, the filler material 112 can be incorporated into a matrix material of the IR-absorbing lamina 100 during its manufacture. In other embodiments, the IR-absorbing film 110 can be manufactured as a bulk film containing the IR-absorbing material.

Embodiments of the imaging unit 100 can further include a package 130 that houses and physically protects the imaging die 104. The package 130 can have a transparent lid 132 that is positioned over the image sensor 102. The transparent lid 132 can allow visible or IR radiation to enter the imaging unit 100, but it protects the active surface of the imaging die 104 from moisture, particulates, and physical contact. The imaging unit 100 can also include wirebonds 140 formed by a wirebonding process that couple electrical contacts 108 of the imaging die 104 to corresponding electrical contacts 122 of the interposer substrate 120. The interposer substrate 120, in turn, can include interconnects 124 for electrically coupling the wirebonds 140 to electrical contacts 126 at an opposing side of the interposer substrate 120. In several embodiments, the electrical contacts 126 are electrically coupled to a support substrate 150 (e.g., another printed circuit board) via metal ball bonds 152. Conductive layers 154 of the support substrate 150 can electrically couple these ball bonds 152 to other electronic components (located at or coupled to the support substrate 150). In further embodiments, the imaging unit 100 is housed within a lens assembly 160 having a lens 162 positioned over the transparent lid 132 of the package 130. The lens 162, for example, can focus and direct visible or IR radiation towards the image sensor 102. Accordingly, the image sensor 102 can use this radiation to produce a readout corresponding to an optical or IR image.

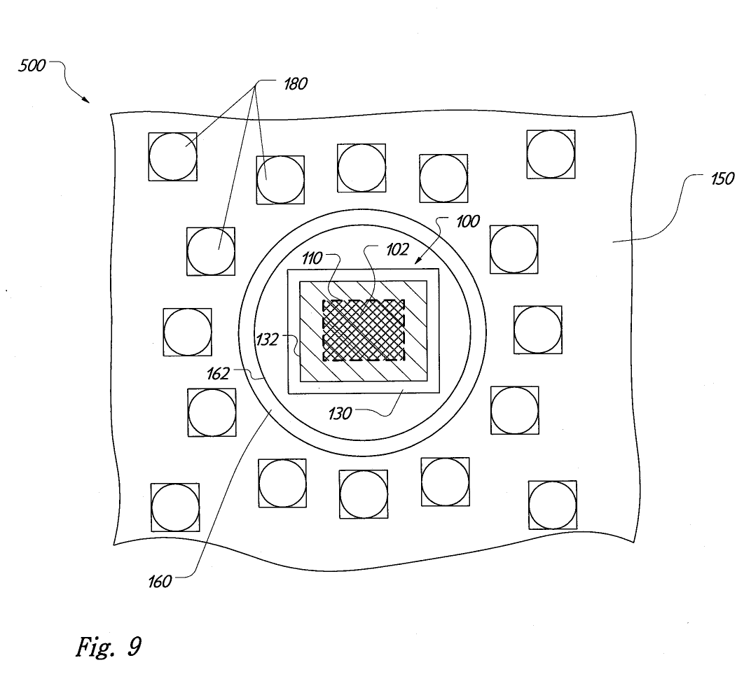

FIGS. 2A and 2B show a cross-sectional side view of the imaging unit 100 and the IR-absorbing lamina 110 inhibiting the transmission and reflection of IR radiation 170. The IR radiation 170, for example, can be produced by an IR light source, such as an IR light-emitting diode 180 of an IR imaging system (described further with reference to FIG. 9). In other examples, the IR radiation 170 may be produced by or reflected from other types of IR or visible light sources. Additionally, the IR radiation 170 can also be a component of incident light at the support substrate 150 or the imaging unit 100, such as bright sunlight, which, in addition to the visible spectra, also includes portions of the infrared spectra. In several examples, the IR radiation 170 is in the near-infrared spectral range of about 750 nm to about 1400 nm. FIG. 2A illustrates an example of the IR radiation 170 “leaking” into the interposer substrate 120 by a waveguide type of phenomena at the support substrate 150. The IR radiation 170 makes its way from the diode 180 into the support substrate 150 through a dielectric core material 156 of the support substrate 150. In general, the dielectric core material 156 (e.g., G10/FR4 circuit board material or other type of epoxy or glass) is generally transparent to IR radiation. However, the conductive layers 154, which partially clad the dielectric core material 156, are generally comprised of metal and metal alloys that reflect infrared radiation. The conductive layers 154 can therefore confine the IR radiation 170 to the support substrate 150 until the light escapes through one or more voids or gaps 158 in the conductive layer 154. The interposer substrate 120, which is also typically manufactured from a printed circuit board material, can likewise have a gap in metal coverage (i.e., between the electrical contacts 126). This gap can provide a transmission path that allows the IR radiation 170 to ultimately reach the interface at the interposer substrate 120 and imaging die 104. Accordingly, the IR-absorbing lamina 110 can be positioned to block the transmission of IR radiation between the interposer substrate 120 and the imaging die 104, preventing the IR radiation from corrupting the readout of the image sensor 102.

FIG. 2B shows another IR leakage mechanism that is mitigated by the IR-absorbing lamina 110. The IR radiation 170 is transmitting through the imaging die 104 and towards the interposer substrate 120. Because the imaging die 104 typically comprises a semiconductor material, such as silicon, it is transparent to infrared spectra. The IR radiation 170 can accordingly travel through the imaging die 104 with little optical resistance. When the IR radiation 170 encounters the interface at the imaging die 104 and interposer substrate 120, at least a portion of this light reflects back into the imaging die 104 (either from reflecting at a metalized portion of the interface or by internal reflection mechanisms). Without the IR absorbing lamina 110, such reflectance of incident IR radiation can also impair the readout of the image sensor 102. The IR-absorbing lamina 110, however, can be positioned to prevent such reflection by absorbing the IR radiation 170.

In contrast to the imaging unit 100, conventional imaging units are vulnerable to such IR radiation leakage. To mitigate these effects, some conventional imaging units employ an IR filter layer at the lid or lens. This layer typically covers the surface of the lid or lens to prevent IR radiation from entering the imaging unit. Conventional IR filters, however, are vulnerable to the waveguide phenomena in which the IR radiation leaks through gaps in the metalized portions of the circuit board substrates at the backside of the die. In addition, because they prevent IR radiation from entering through the lens of an imaging unit, conventional IR blocking filters cannot be readily used in IR imaging systems.

Furthermore, embodiments of the IR-absorbing lamina 110 provide a uniformly distributed amount of the filler material 112 between the imaging die 104 and the interposer substrate 120. Conventional die attach pastes, by contrast, are flowable, and they tend to be viscous such that they have “bleed-out” regions or voids that have no paste material. These voids are often created when paste material migrates away from localized regions of high mechanical pressure attributed to pressing an imaging die together with an interposer substrate. Because these voids have no paste material, they cannot contain filler material and therefore cannot effectively block the transmission/reflection of IR radiation. Still further, die attach pastes are typically dispensed with injection equipment that includes a pump or dispenser that requires periodic maintenance and/or cleaning. Such maintenance or cleaning can contribute to manufacturing cost of a microelectronic device. However, the cost associated with implementing the IR-absorbing lamina 110 is considerably less expensive. For example, the IR-absorbing lamina 110 can be a die attach film or other type of laminated sheet that is manually applied or applied with relatively inexpensive laminating equipment. This type of equipment generally requires less maintenance and/or cleaning than the injection equipment used with die-attach pastes.

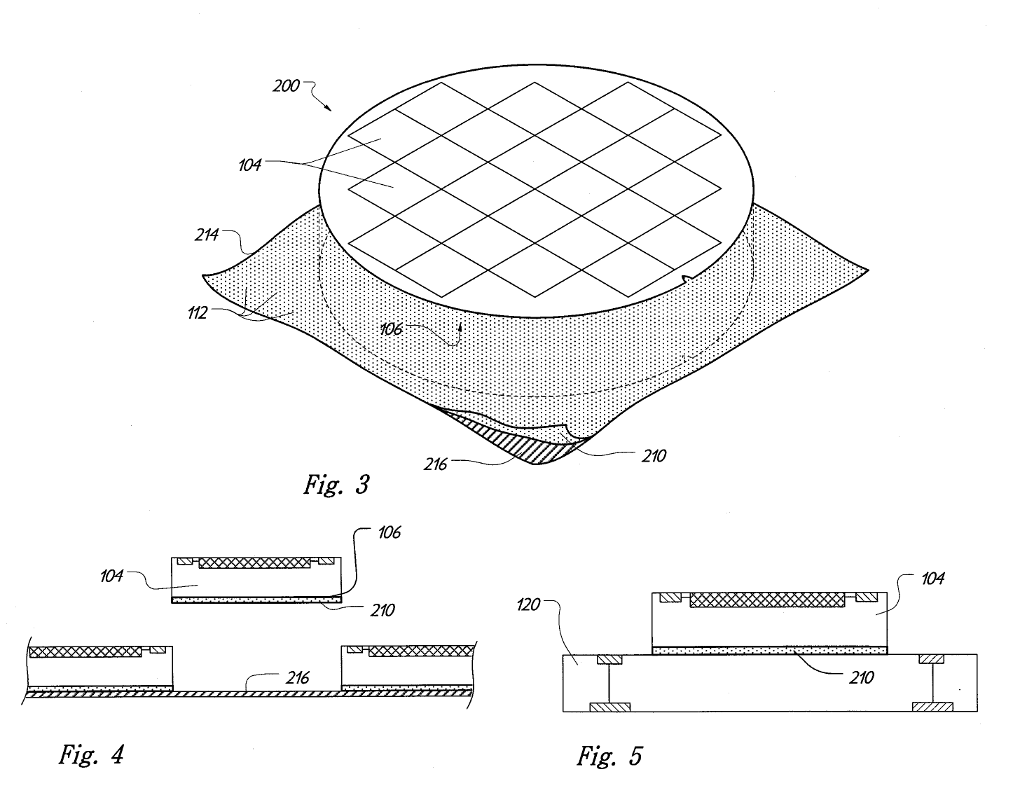

FIGS. 3-5 illustrate stages of an embodiment of a method for fabricating IR-absorbing lamina in accordance with several embodiments of the disclosure. FIG. 3 is an isometric view of a microelectronic imager workpiece 200 that includes a plurality of imaging dies 104. The imager workpiece 200 can be laminated with a die attach film 214. For example, the die attach film 214 can be physically pressed against the backside die surface 106 (either manually or with a laminating tool). The die attach film 214 can have an adhesive layer 210 and a base layer 216 attached to the adhesive layer 210. The filler material 112 is incorporated into at least the adhesive layer 210, but in other embodiments the filler material 112 can be incorporated into both the adhesive layer 210 and the base layer 216. The adhesive layer 210 can also have a backing layer (not shown), including the filler material 112, and an additional adhesive on the opposite side of the backing layer. The base layer 216 can further include adhesive or non adhesive components (not shown). The non adhesive component, for example, can be non stick, and the adhesive component can provide a temporary bond between the base layer 216 and the adhesive layer 210. This temporary bond can hold the die attach film 214 to the backside die surface 106 but allow individual dies to be subsequently “die picked” after singulation (described further with reference to FIG. 4). For example, the adhesive strength of the adhesive component of the base layer 216 may be weakened by treatment with ultraviolet (UV) light. In a specific embodiment, the die attach film 214 is a dicing die attach film (DDAF) or 2-in-1 film that is both a protective layer for die singulation as well as an instrument for positioning the adhesive layer 210 at the backside die surface 106.

FIG. 4 is a cross-sectional side view of an individual imaging die 104 that is singulated and die picked from the imager workpiece. Die singulation mechanically isolates the imaging die 104 from other imaging dies and can be carried out by processes such as scribing and breaking, mechanical sawing (e.g., using a dicing saw), or laser cutting. After singulation, the imaging die 104 can be separated from the base layer 216 using a die pick tool (e.g., a vacuum tool or die collet). In the embodiment shown in FIG. 4, a section of the adhesive layer 210 remains fixed to the backside die surface 106 after die picking, but the base layer 216 is separated from the adhesive layer 210.

FIG. 5 is a cross-sectional side view of the imaging die 104 attached to the interposer substrate 120 via the adhesive layer 210. In operation, a machine presses the adhesive layer 210 against the interposer substrate 120 to form physically couple the imaging die 104 to the interposer substrate 120. In many embodiments, the adhesive layer 210 can also undergo a temperature treatment, radiation treatment, or other curing procedures to increase the bond strength between the imaging die 104 and the interposer substrate 120.

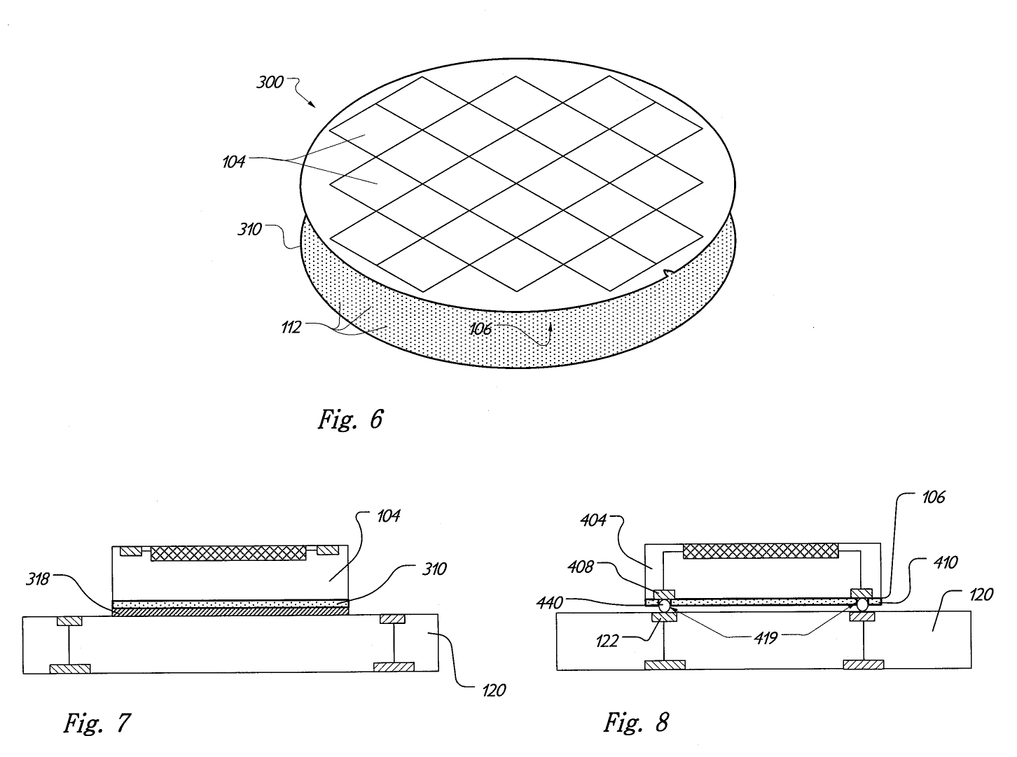

FIGS. 6 and 7 illustrate stages of additional embodiments of fabricating an imaging unit that includes an IR-absorbing lamina. FIG. 6 is an isometric view of a microelectronic imager workpiece 300 that includes a plurality of imaging dies 104. The imager workpiece 300 can be laminated with a non-viscous polymer-based sheet 310 made from a material such as a plastic or resin and further including the filler material 112. In many embodiments, the polymer sheet 310 is bonded to the backside die surface 106 by a high temperature curing process. In a specific embodiment, the polymer sheet can be a protective film such as those used for flip-chip applications and provided by Lintec Corporation of Japan. Such films are conventionally attached to the top-side surface of a flip chip assembly (i.e., the back side of a downwardly facing flip-chip die) and protect the flip-chip die during die singulation and other types of handling. After laminating the polymer sheet 310, an individual imaging die 104 can be singulated and die picked from the workpiece 300. The individual imaging die 104 can then be attached to an interposer substrate via an intermediary material (e.g., a die attach paste or die attach film). For example, FIG. 7 is a cross-sectional side view showing the imaging die 104 coupled to the interposer substrate 120 via the polymer sheet 310 and an intermediary die attach material 318.

FIG. 8 is a cross-sectional side view of another embodiment of an IR-absorbing lamina 410 that is positioned between a bump-bonded imaging die 404 and an interposer substrate 120. In lieu of wire bonds, metal bump bonds 440 (formed by a bump bonding process) electrically couple electrical contacts 408 at the backside die surface 106 to the electrical contacts 122 of the interposer substrate 120. The IR-absorbing lamina 410 includes regions 419 that allow the bump bonds 440 to pass through the IR-absorbing lamina 410 and contact the electrical contacts 408. The regions 419 can be formed by etching, cutting, or otherwise removing material from the IR-absorbing lamina 410. In many embodiments, individual regions 419 have a surface area (parallel with the backside die surface 106) that is generally smaller than the surface area of the electrical contacts 408 at the imaging die 104 or the surface area of the electrical contacts 122 at the interposer substrate 120.

Embodiments of the IR-absorbing lamina may have other features. For example, in many embodiments the filler material is employed at a specific concentration within a laminated sheet. If the filler material is carbon black, IR-absorbing laminas can have a volumetric portion as small as 0.05%. In addition, generally thick IR-absorbing laminas may have an even smaller volumetric portion, such as those that are thicker than 10 μm. In other examples, the percentage concentration may be configured with respect to other features of the IR-absorbing lamina. For example, decreasing the volumetric percentage of the filler material can generally increase the adhesive strength of a die attach film.

Embodiments of the IR imaging unit may also have other features. For example, imaging units can be stand-alone parts having an interposer substrate that is mounted to a support substrate. Alternatively, an imaging die can be directly mounted to such a support substrate without an intermediary interposer substrate. Further, imaging units may also be housed in various types of packages. For example, in FIG. 1, in lieu of the transparent lid 132, the imaging unit 100 can include a lens for the purpose of focusing light at the image sensor 102 (separate lid and lens assembly 160 could thus be omitted). Also, the package 130 and the lens assembly 160 may comprise a variety of materials, such as plastics, metals, glasses, etc., that physically support the corresponding transparent lid 132 and lens 162 and generally shield the imager from visible or infrared light.

Embodiments of the IR-absorbing laminas and imager units may also be incorporated into any of a myriad of larger or more complex electrical or optical systems. For example, non-optical systems can use embodiments of the IR-absorbing lamina in IR radiation environments. Such non-optical systems can have microelectronic devices employing the IR-absorbing lamina to suppress the IR waveguide phenomena in a printed circuit board.

As a specific embodiment of a system, FIG. 9 shows a top plan view of an IR imaging system 500 that employs the imaging unit 100, including the IR-absorbing lamina 110 (drawn in phantom). The imaging system 500 can also include a plurality light-emitting diodes 180 and the lens assembly 160, which is at least partially surrounded by the diodes 180. The lens assembly 160 and the package 130 can prevent light emitted by the diodes 180 from being directly transmitted to the imager sensor 102. For example, the bodies of the lens assembly 160 and the package 130 can be opaque to visible or infrared light. The image sensor 102 can therefore be shielded from infrared radiation that travels in generally lateral directions towards the image sensor 102 and parallel with the support substrate 150. The transparent lens 162 and lid 132, on the other hand, accept infrared radiation that generally travels in perpendicular and transverse directions towards the image sensor 102. Accordingly, the image sensor 102 can generally receive infrared radiation when an object reflects it back towards the lens 162.

From the foregoing, it will be appreciated that specific embodiments have been described herein for purposes of illustration, but well-known structures and functions have not been shown or described in detail to avoid unnecessarily obscuring the description of the embodiments. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same feature or additional types of other features are not precluded. It will also be appreciated that specific embodiments have been described herein for purposes of illustration but that various modifications may be made within the claimed subject matter. For example, many of the elements of one embodiment can be combined with other embodiments in addition to, or in lieu of, the elements of the other embodiments. Accordingly, the invention is not limited except as by the appended claims.

We claim:

1. A method of manufacturing a microelectronic imaging unit, the method comprising:
attaching an infrared-absorbing lamina to a backside die surface of an imager workpiece having at least one imaging die, the infrared-absorbing lamina including an infrared-absorbing material that absorbs electromagnetic radiation in the near-infrared frequency spectra;
singulating from the imager workpiece the imaging die and a section of the infrared-absorbing lamina attached to the imaging die; and
coupling the backside die surface to an interposer substrate, wherein at least a portion of the infrared-absorbing lamina is positioned between the interposer substrate and the imaging die.

2. The method of claim 1 wherein the infrared-absorbing lamina comprises a die attach film having a base film and an adhesive layer, and wherein attaching the infrared-absorbing lamina comprises:
pressing the adhesive layer against the backside die surface, wherein at least the adhesive layer includes the infrared-absorbing material; and
removing the base film from the adhesive layer, wherein the adhesive layer remains coupled to the backside die surface.

3. The method of claim 2 wherein coupling the backside die surface to the interposer substrate comprises attaching the adhesive layer to the interposer substrate.

4. The method of claim 1 wherein the infrared-absorbing lamina comprises a non-flowable polymeric film containing the infrared-absorbing material, and wherein attaching the infrared-absorbing lamina comprises:
positioning the polymeric film at the backside die surface; and
curing the polymeric film.

5. The method of claim 4 wherein coupling the backside die surface to the interposer substrate includes using at least one of a die attach film and a die attach paste to couple the polymeric film to the interposer substrate.

6. The method of claim 1 wherein the infrared-absorbing material includes at least one of carbon black, aluminum trihydroxide, aluminum borate, calcium borate, calcium carbonate, lanthanum borite, and indium tin oxide.

7. The method of claim 1 wherein the infrared-absorbing lamina comprises at least 0.05% carbon black by volume.

8. A method for manufacturing a microelectronic imaging unit, the method comprising:
aligning a lamina comprising a pre-formed polymeric film and an infrared-absorbing material with an imaging die;
covering a backside surface of the imaging die with the pre-formed polymeric film; and
attaching an interposer substrate to at least a portion of the pre-formed polymeric film at the backside surface of the imaging die.

9. The method of claim 8, further comprising forming a package that is attached to the interposer substrate and houses the imaging die, the package including at least one of a transparent lid and lens that is positioned over at least a portion of the imaging die.

10. The method of claim 8, further comprising:
coupling electrical contacts of the imaging die to electrical contacts at a first side of the interposer substrate; and
removing a portion of the continuous film that corresponds with a bonding location at an individual electrical contact of the interposer substrate.

11. The method of claim 11 wherein coupling the electrical contacts of the imaging die is carried out by at least one of a wire bonding process and a bump bonding process.

12. A method for inhibiting the transmission of electromagnetic radiation between an interposer substrate and a microelectronic die, the method comprising:
coupling a microelectronic die to an interposer substrate; and
positioning an infrared-absorbing lamina between the microelectronic die and the interposer substrate carrying the microelectronic die, the infrared-absorbing lamina including a material that absorbs infrared light, and the interposer substrate including a region adjacent to the infrared-absorbing lamina that is generally transparent to the infrared light.

13. The method of claim 12 wherein the infrared-absorbing lamina comprises an adhesive and the material that absorbs infrared radiation is a filler material in the adhesive.

14. The method of claim 13 wherein the filler material includes at least one of carbon black, aluminum trihydroxide, aluminum borate, calcium borate, calcium carbonate, lanthanum borite, and indium tin oxide.

15. The method of claim 12 wherein the infrared-absorbing lamina is a continuous film composed of a non-viscous polymeric material.

16. A microelectronic imaging unit, comprising:
a microelectronic imaging die including a backside die surface;
an infrared-absorbing lamina attached to at least a portion of the backside die surface, the infrared-absorbing lamina including a material that filters out infrared radiation; and
an interposer substrate coupled to the imaging die, wherein the infrared-absorbing lamina is between the backside die surface and the interposer substrate.

17. The imaging device of claim 16 wherein the infrared-absorbing lamina comprises an adhesive layer associated with a die attach film.

18. The imaging device of claim 16 wherein the infrared-absorbing lamina comprises a polymer based sheet.

19. The imaging device of claim 16 wherein the infrared-absorbing lamina is positioned to cover a non metalized region of the interposer substrate.

20. The imaging device of claim 16 wherein the infrared-absorbing lamina is positioned to inhibit electromagnetic radiation from reflecting into the backside die surface.

21. An infrared imaging system, comprising:
a support substrate;
a microelectronic imaging unit electrically coupled to the support substrate and including an imaging die having an image sensor;
at least one infrared light-emitting diode coupled to the support substrate and configured to output infrared light; and
a radiation-absorbing element between the backside surface of the imaging die and the support substrate, wherein the radiation absorbing element is not transmissive to infrared radiation.

22. The infrared imaging system of claim 21, further comprising at least one of a package and a lens assembly, the package and/or lens assembly housing the imaging die and including a lens that is positioned over the image sensor.

23. The infrared imaging system of claim 21 wherein the radiation-absorbing element is positioned to inhibit at least a portion of the infrared light that is transmitted towards the imaging die and through the support substrate.

24. The infrared imaging system of claim 21 wherein the radiation-absorbing element comprises a non-flowable polymeric film and/or an adhesive layer associated with a die attach film.

25. The infrared imaging system of claim 21 wherein the radiation-absorbing element comprises at least a 0.05% volumetric concentration of carbon black.
